(19) United States
(12) Patent Application Publication
(10) Pub. No.: US 2014/0347792 A1
(43) Pub. Date: Nov. 27, 2014

(54) ELECTRONIC DEVICE WITH STOPPING PLATE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: GUAN-DONG ZHAO, Shenzhen (CN); XUE-FENG WAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/034,578

(22) Filed: Sep. 24, 2013

(30) Foreign Application Priority Data
May 23, 2013 (CN) 2013202839888

(51) Int. Cl. H05K 5/02

(52) U.S. Cl. CPC H05K 5/0221
USPC 361/679.01

(57) ABSTRACT

An electronic device includes a top case having at least one inserting tab, a bottom case defining at least one latching slit corresponding to the at least one inserting tab, and at least one stopping plate secured to the bottom case and corresponding to the at least one latching slit. The top case is latched to the bottom case by the inserting tab being inserted into the at least one latching slit. When the inserting tab is unaligned with the latching slit, the stopping plate blocks the inserting tab and guides the inserting tab to be inserted into the latching slit, to prevent the top case from misplacement.

### BACKGROUND

1. Technical Field

The present disclosure relates to electronic devices, and particularly to the housing of an electronic device.

2. Description of Related Art

Electronic devices, such as, set-top box, DVD player, or the like, generally include a housing for receiving circuit board, power supply and other electronic components. The housing includes a top case and a bottom case engaging with each other. The top case has a number of inserting members, and the bottom case defines a number of latching slits corresponding to the inserting members. The top case is latched to the bottom case by the inserting members being inserted into the latching slits. However, because the latching slits are narrow, it is difficult to align the inserting members with the corresponding latching slits, which may result in misplacement of the top case.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partial perspective view of an electronic device in accordance with an embodiment.

FIG. 2 is a disassembled view of the electronic device in FIG. 1.

FIG. 3 is an enlarged view of part III in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

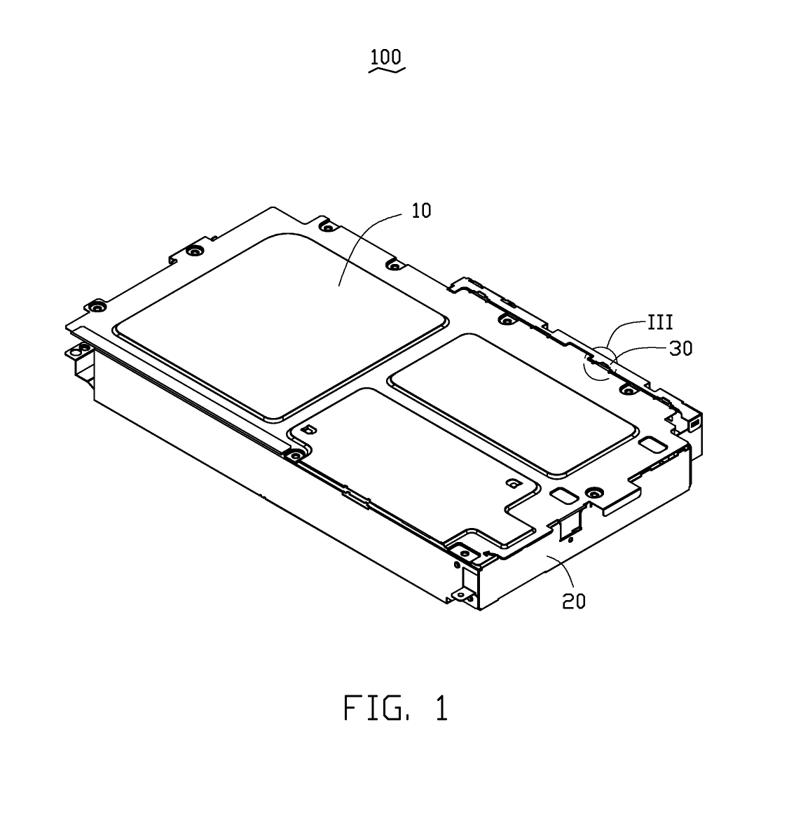

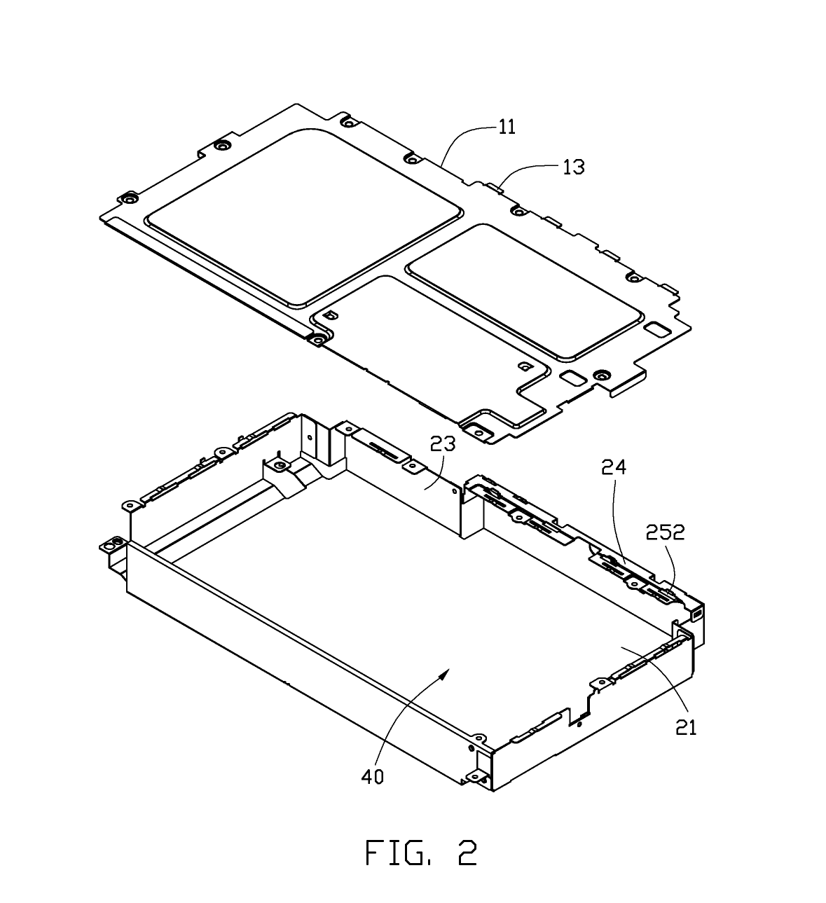

FIG. 1 illustrates an electronic device 100. The electronic device 100 includes a top case 10, a bottom case 20, and a number of stopping plates 30. The top case 10 engages with the bottom case 20 to define a receiving space 40 (see FIG. 2) for receiving circuit board, power supply, and other electronic components (not shown). The stopping plates 30 are secured to the bottom case 20 and prevent the top case 10 from misplacement when the top case 10 is latched to bottom case 20. The electronic device 200 can be a set-top box, or a DVD player, for example. In the embodiment, the electronic device 200 is a set-top box.

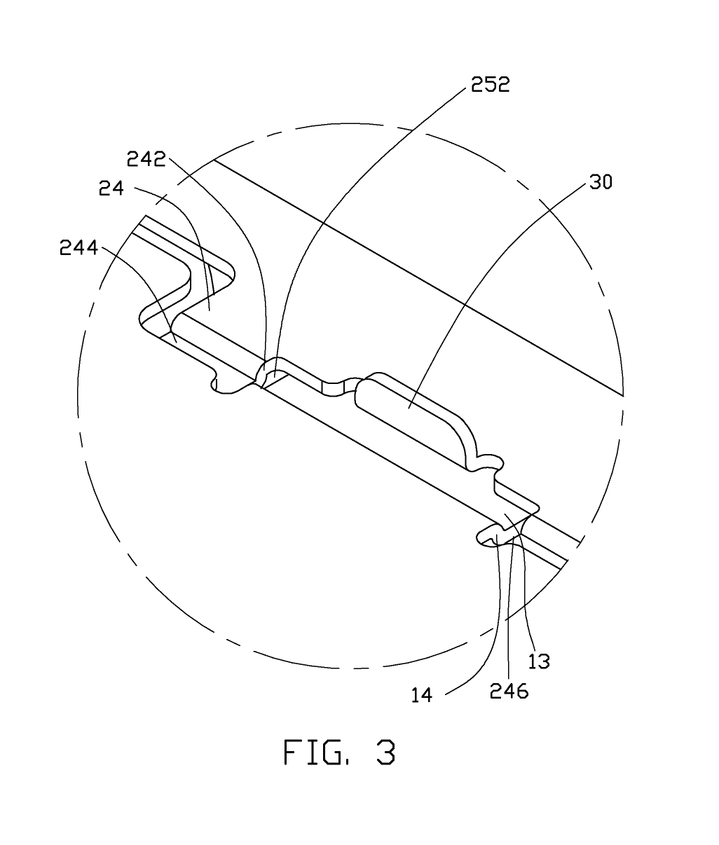

FIG. 2 shows that the top case 10 is substantially a rectangular plate. A number of inserting tabs 13 are arranged at a rim 11 (hereinafter, a first rim 11) of the top case 10. In the embodiment, each inserting tab 13 bends downwardly from the first rim 11 and further extends in a direction parallel to the top case 10, to form a step 14 (see FIG. 3).

The bottom case 20 includes a base 21 and a number of sidewalls extending from rims of the base 21. One of the sidewalls (hereinafter, the first sidewall 23) corresponds to the first rim 11 of the top case 10. A latching plate 24 extends inwardly from an end of the first sidewall 23 away from the base 21. The latching plate 24 is parallel to the base 21. An end of the latching plate 24 away from the first sidewall 23 bends toward the base 21 to form a connecting portion 242. The distal end of the connecting portion 242 further extends in a direction parallel to the base 21 to form a supporting portion 244. The supporting portion 244 supports the top case 10 when the top case 10 is latched to the bottom case 20. The connecting portion 242 defines a number of latching slits 252 corresponding to the inserting tabs 13. The width of each latching slit 252 in a longitudinal direction of the latching plate 24 is slightly greater than the width of the corresponding inserting tab 13. The supporting portion 244 further defines a number of cutouts 246 corresponding to and communicating with the latching slits 252. The cutouts 246 make room for the step 14 when the inserting tabs 13 are inserted into the corresponding latching slits 252.

The stopping plates 30 are secured to the latching plate 24 and correspond to the latching slits 252. In the embodiment, each stopping plate 30 slantingly extends upwardly from a sidewall of the corresponding latching slit 252 adjacent to the first sidewall 23, and protrudes out of a top surface of the latching plate 24 opposite to the base 21.

FIG. 3 shows that in order to latch the top case 10 to the bottom case 20, the inserting tabs 13 are inserted into the corresponding latching slits 252 in a direction perpendicular to the first sidewall 23, with the steps 14 abutting a sidewall of the latching slit 252 adjacent to the first sidewall 23. During assembly, when the inserting tabs 13 are not aligned with the corresponding latching slits 252 and move along the top surface of the latching plate 24, the stopping plates 30 block the inserting tabs 13 and guide the inserting tabs 13 to be inserted into the latching slits 252. As a result, the top case 10 is protected from misplacement.

Although information as to, and advantages of, the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
a top case having at least one inserting tab;
a bottom case defining at least one latching slit corresponding to the at least one inserting tab; and
at least one stopping plate secured to the bottom case and corresponding to the at least one latching slit;
wherein the top case is latched to the bottom case by the at least one inserting tab being inserted into the at least one latching slit; when the at least one inserting tab is unaligned with the at least one latching slit, the at least one stopping plate blocks the at least one inserting tab and guides the at least one inserting tab to be inserted into the at least one latching slit, to prevent the top case from misplacement.

2. The electronic device of claim 1, wherein the bottom case comprises a base and a first sidewall protruding from the base, an end of the first sidewall away from the base extends inwardly to form a latching plate, the at least one stopping plate is arranged on the latching plate.

3. The electronic device of claim 2, wherein an end of the latching plate away from the first sidewall bents toward the base to form a connecting portion, the distal end of the connecting portion extends in a direction parallel to the base to form a supporting portion, the supporting portion supports the top case when the top case is latched to the bottom case.

4. The electronic device of claim 3, wherein the connecting portion defines the at least one latching slit, at least one stopping plate slantingly extends upwardly from a sidewall of the at least one latching slit adjacent to the first sidewall.

5. The electronic device of claim 2, wherein the at least one inserting tab bents downwardly from a first rim of the top case corresponding to the first sidewall, and further extends in a direction parallel to the top case to form a step, when the top case is latched to the bottom case, the step abuts a sidewall of the at least one latching slit adjacent to the first sidewall.

6. The electronic device of claim 5, wherein the supporting portion defines at least one cutout corresponding to and communicating with the at least one latching slit, the at least one latching slit makes room for the step when the at least one inserting tab being inserted into the at least one latching slit.
